(19) United States
(12) Patent Application Publication
(10) Pub. No.: US 2026/0107708 A1
(43) Pub. Date: Apr. 16, 2026

(54) SUBSTRATE PROCESSING METHOD AND SUBSTRATE PROCESSING APPARATUS

(71) Applicant: Tokyo Electron Limited, Tokyo (JP)

(72) Inventors: Hitoshi KATO, Iwate (JP); Hiroyuki KIKUCHI, Iwate (JP); Hidenobu SATO, Iwate (JP); Ibuki HAYASHI, Iwate (JP)

(21) Appl. No.: 19/354,046

(22) Filed: Oct. 9, 2025

(30) Foreign Application Priority Data
Oct. 11, 2024 (JP) 2024-178674

(51) Int. Cl. H01L 21/02; H01L 21/67

(52) U.S. Cl. CPC H10P 14/6529; H10P 72/0421

(57) ABSTRACT

A substrate processing method according to an aspect of the present disclosure includes: preparing a substrate having a silicon film on a surface thereof; and supplying chlorine gas to the substrate, thereby etching the silicon film. The etching of the silicon film includes: retaining, in a retaining portion, the chlorine gas before being supplied to the substrate, and generating chlorine radicals from the chlorine gas by irradiating, with an ultraviolet ray, the chlorine gas inside the retaining portion.

### CROSS-REFERENCE TO RELATED APPLICATIONS

This application is based upon and claims priority to Japanese Patent Application No. 2024-178674 filed on October 11, 2024, the entire contents of which are incorporated herein by reference.

### TECHNICAL FIELD

The present disclosure relates to a substrate processing method and a substrate processing apparatus.

### BACKGROUND

Japanese Patent Application Laid-Open Publication No. 2022-113991 discloses a technique of repeatedly performing film formation and etching to deposit a silicon film in a recess. In the etching, a gas obtained by adding hydrogen gas to chlorine gas is used.

### SUMMARY

A substrate processing method according to an aspect of the present disclosure includes: preparing a substrate having a silicon film on a surface thereof; and supplying chlorine gas to the substrate, thereby etching the silicon film. The etching of the silicon film includes: retaining, in a retaining portion, the chlorine gas before being supplied to the substrate, and generating chlorine radicals from the chlorine gas by irradiating, with an ultraviolet ray, the chlorine gas inside the retaining portion.

### BRIEF DESCRIPTION OF THE DRAWINGS

FIG. 1 is a cross-sectional view illustrating a substrate processing apparatus according to an embodiment;

FIG. 2 is a perspective view illustrating a configuration inside a vacuum chamber of the substrate processing apparatus of FIG. 1;

FIG. 3 is a plan view illustrating the configuration inside the vacuum chamber of the substrate processing apparatus of FIG. 1;

FIG. 4 is a cross-sectional view of the vacuum chamber along the circumferential direction of a rotary table of the substrate processing apparatus of FIG. 1;

FIG. 5 is another cross-sectional view of the substrate processing apparatus of FIG. 1;

FIG. 6 is a cross-sectional view (1) illustrating an example of a plasma source;

FIG. 7 is a cross-sectional view (2) illustrating the example of the plasma source;

FIG. 8 is a plan view illustrating the example of the plasma source;

FIG. 9 is an exploded perspective view illustrating an example of a gas heater;

FIG. 10 is a plan view (1) illustrating the example of the gas heater;

FIG. 11 is a plan view (2) illustrating the example of the gas heater;

FIG. 12 is a cross-sectional view (1) illustrating the example of the gas heater;

FIG. 13 is a cross-sectional view (2) illustrating the example of the gas heater;

FIG. 14 is a cross-sectional view (1) illustrating a substrate processing method according to an embodiment;

FIG. 15 is a cross-sectional view (2) illustrating the substrate processing method according to an embodiment; and

FIG. 16 is a diagram showing measurement results of etching rates of a silicon film.

### DETAILED DESCRIPTION

Hereinafter, non-limiting exemplary embodiments of the present disclosure will be described with reference to the accompanying drawings. Throughout all of the accompanying drawings, the same or corresponding members or parts are denoted by the same or corresponding reference numerals, and redundant descriptions thereof will be omitted.

### Substrate Processing Apparatus

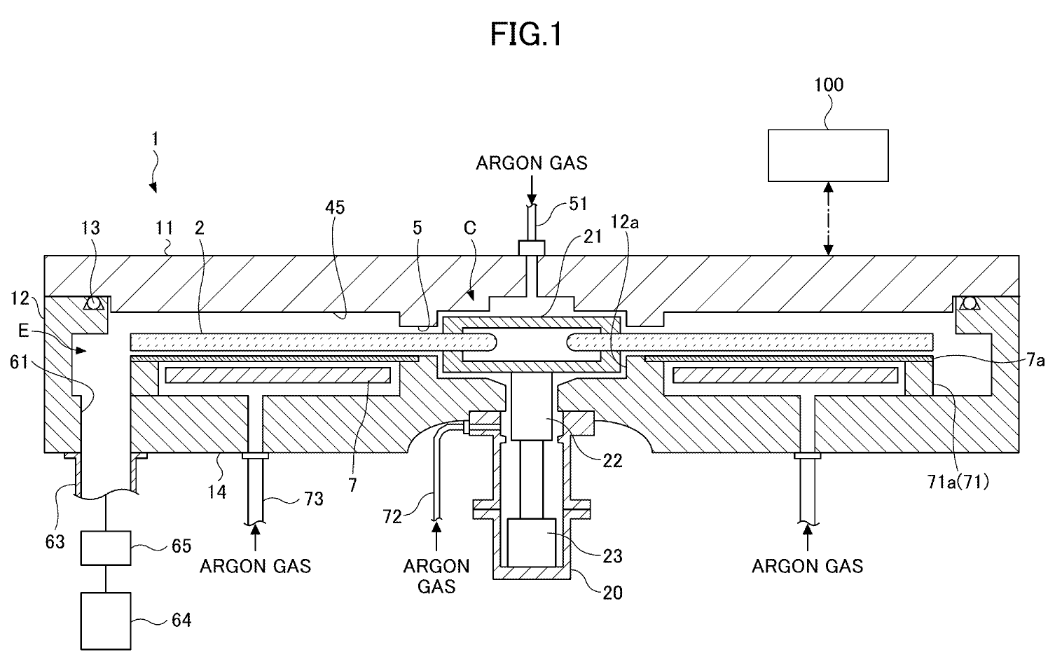

A substrate processing apparatus according to an embodiment will be described. Referring to FIGS. 1 to 3, a substrate processing apparatus includes a flat vacuum chamber 1 and a rotary table 2. The vacuum chamber 1 has a substantially circular planar shape, and the rotary table 2 is provided inside the vacuum chamber 1 and has a rotation center at the center of the vacuum chamber 1.

The vacuum chamber 1 has a chamber body 12 and a top plate 11. The chamber body 12 has a bottomed cylindrical shape, and the top plate 11 is airtightly and detachably disposed on an upper surface of the chamber body 12 via a seal member 13. The seal member 13 is, for example, an O-ring.

The rotary table 2 is fixed to a cylindrical core 21 at the center of the rotary table 2. The core 21 is fixed to an upper end of a rotary shaft 22 extending in the vertical direction. The rotary shaft 22 penetrates a bottom 14 of the vacuum chamber 1, and a lower end of the rotary shaft 22 is attached to a driver 23 configured to rotate the rotary shaft 22 about a vertical axis. The rotary shaft 22 and the driver 23 are housed in a tubular case body 20 having an open top. A flange provided on the upper surface of the case body 20 is airtightly attached to a lower surface of the bottom 14 of the vacuum chamber 1. This maintains airtightness between the internal atmosphere and the external atmosphere of the case body 20.

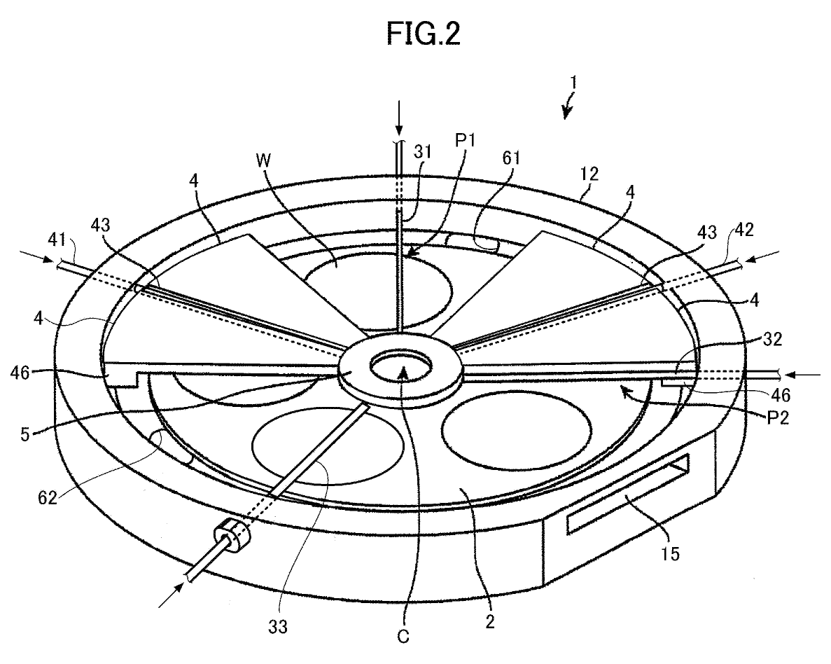

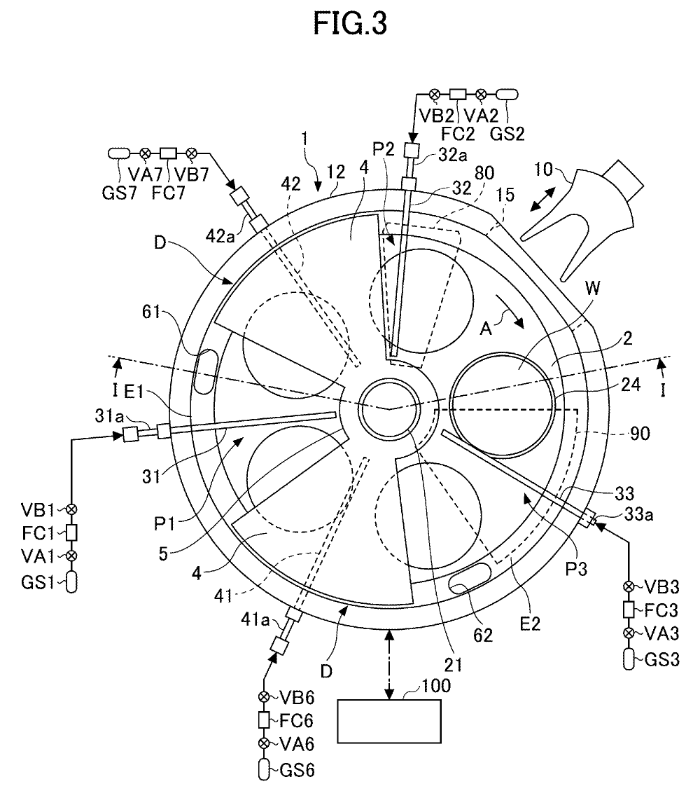

As illustrated in FIGS. 2 and 3, circular stages 24 are provided on a surface of the rotary table 2 to place a plurality of (in the illustrated example, five) substrates W along the rotation direction (circumferential direction). The substrates W are, for example, semiconductor wafers such as silicon wafers. FIG. 3 illustrates one substrate W on one stage 24 for convenience of illustration. The stage 24 has an inner diameter slightly larger than the diameter of the substrate W by, for example, 4 mm, and has a depth substantially equal to the thickness of the substrate W. In this case, when the substrate W is accommodated in the stage 24, the surface of the substrate W and the surface of the rotary table 2 (a region where the substrate W is not placed) are at the same height. In the bottom of the stage 24, through-holes (not shown) are formed. For example, three lift pins (not shown) penetrate the through-holes. The lift pins are configured to support an underside of the substrate W so as to raise and lower the substrate W.

FIGS. 2 and 3 are explanatory views illustrating a structure inside the vacuum chamber 1, and the top plate 11 is omitted for convenience of explanation. As illustrated in FIGS. 2 and 3, process gas nozzles 31, 32, and 33 and separation gas nozzles 41 and 42 are disposed above the rotary table 2, spaced apart from one another in the circumferential direction of the vacuum chamber 1. In the illustrated example, the process gas nozzle 33, the separation gas nozzle 41, the process gas nozzle 31, the separation gas nozzle 42, and the process gas nozzle 32 are arranged in this order clockwise (the rotation direction indicated by an arrow A in FIG. 3) from a transfer port 15 described later. The process gas nozzles 31, 32, and 33 and the separation gas nozzles 41 and 42 are each formed of, for example, quartz. Gas introduction ports 31a, 32a, 33a, 41a, and 42a, serving as base ends of the respective process gas nozzles 31, 32, and 33 and the separation gas nozzles 41 and 42, are fixed to an outer peripheral wall of the chamber body 12. Accordingly, the process gas nozzles 31, 32, and 33 and the separation gas nozzles 41 and 42 are each inserted into the vacuum chamber 1 from the outer peripheral wall of the vacuum chamber 1, and are attached so as to extend horizontally relative to the rotary table 2 in the radial direction of the chamber body 12.

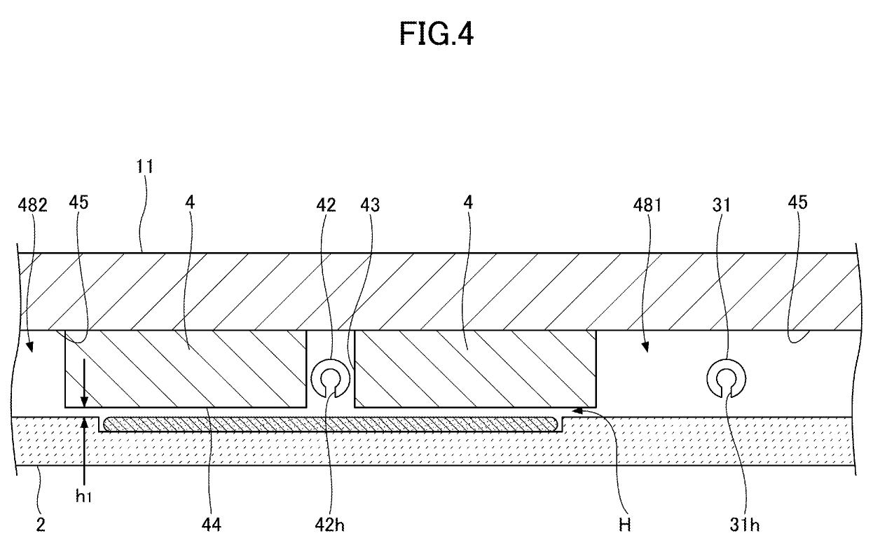

A supply source GS1 filled with a source gas is connected to the process gas nozzle 31. The process gas nozzle 31 supplies the source gas from the supply source GS1 into the vacuum chamber 1. A flow rate of the source gas from the supply source GS1 is controlled by a flow rate controller FC1. The supply and shutoff of the source gas from the supply source GS1 into the vacuum chamber 1 are controlled by valves VA1 and VB1. The source gas is, for example, dichlorosilane gas. A supply source filled with a different gas, for example, a dilution gas such as argon gas, may further be connected to the process gas nozzle 31. The process gas nozzle 31 is provided with discharge holes 31h (FIG. 4) opening toward the rotary table 2. The discharge holes 31h are arranged along a longitudinal direction of the process gas nozzle 31 at intervals of, for example, 10 mm. A region below the process gas nozzle 31 serves as an adsorption region P1 for adsorbing the source gas onto the substrate W. The process gas nozzle 31 is an example of a source gas supply.

A supply source GS2 filled with a nitriding gas is connected to the process gas nozzle 32. The process gas nozzle 32 supplies the nitriding gas from the supply source GS2 into the vacuum chamber 1. A flow rate of the nitriding gas from the supply source GS2 is controlled by a flow rate controller FC2. The supply and shutoff of the nitriding gas from the supply source GS2 into the vacuum chamber 1 are controlled by valves VA2 and VB2. The nitriding gas is, for example, ammonia (NH₃) gas. A supply source filled with a different gas, for example, a dilution gas such as argon gas, may further be connected to the process gas nozzle 32. A region below the process gas nozzle 32 serves as a nitriding region P2 for nitriding the source gas adsorbed onto the substrate W in the adsorption region P1. The process gas nozzle 32 is an example of a nitriding gas supply. A plasma source 80 is provided above the process gas nozzle 32, as indicated by a broken line in FIG. 3 in a simplified manner. The plasma source 80 will be described later.

A supply source GS3 filled with chlorine gas is connected to the process gas nozzle 33. The process gas nozzle 33 supplies the chlorine gas from the supply source GS3 into the vacuum chamber 1. A flow rate of the chlorine gas from the supply source GS3 is controlled by a flow rate controller FC3. The supply and shutoff of the chlorine gas from the supply source GS3 into the vacuum chamber 1 are controlled by valves VA3 and VB3. A supply source filled with a different gas, for example, a dilution gas such as argon gas, may further be connected to the process gas nozzle 33. A region below the process gas nozzle 33 serves as an etching region P3 for etching a film using chlorine gas. The process gas nozzle 33 is an example of a chlorine gas supply. A gas heater 90 is provided above the process gas nozzle 33, as indicated by a broken line in FIG. 3 in a simplified manner. The gas heater 90 will be described later.

A supply source GS6 filled with a separation gas is connected to the separation gas nozzle 41. The separation gas nozzle 41 supplies the separation gas from the supply source GS6 into the vacuum chamber 1. A flow rate of the separation gas from the supply source GS6 is controlled by a flow rate controller FC6. The supply and shutoff of the separation gas from the supply source GS6 into the vacuum chamber 1 are controlled by valves VA6 and VB6. The separation gas is, for example, an inert gas such as argon gas.

A supply source GS7 filled with a separation gas is connected to the separation gas nozzle 42. The separation gas nozzle 42 supplies the separation gas from the supply source GS7 into the vacuum chamber 1. A flow rate of the separation gas from the supply source GS7 is controlled by a flow rate controller FC7. The supply and shutoff of the separation gas from the supply source GS7 into the vacuum chamber 1 are controlled by valves VA7 and VB7. The separation gas is, for example, an inert gas such as argon gas.

Referring to FIGS. 2 and 3, two protruding portions 4 are provided in the vacuum chamber 1. The protruding portions 4, together with the separation gas nozzles 41 and 42, form separation regions D. Therefore, as described later, the protruding portions 4 are attached to an underside of the top plate 11, extending toward the rotary table 2. The protruding portions 4 have a sectoral planar shape with their tops cut in an arc. Each protruding portion 4 is disposed such that an inner arc thereof is connected to a projecting portion 5 (described later), and an outer arc of the protruding portion 4 follows an inner peripheral surface of the chamber body 12 of the vacuum chamber 1.

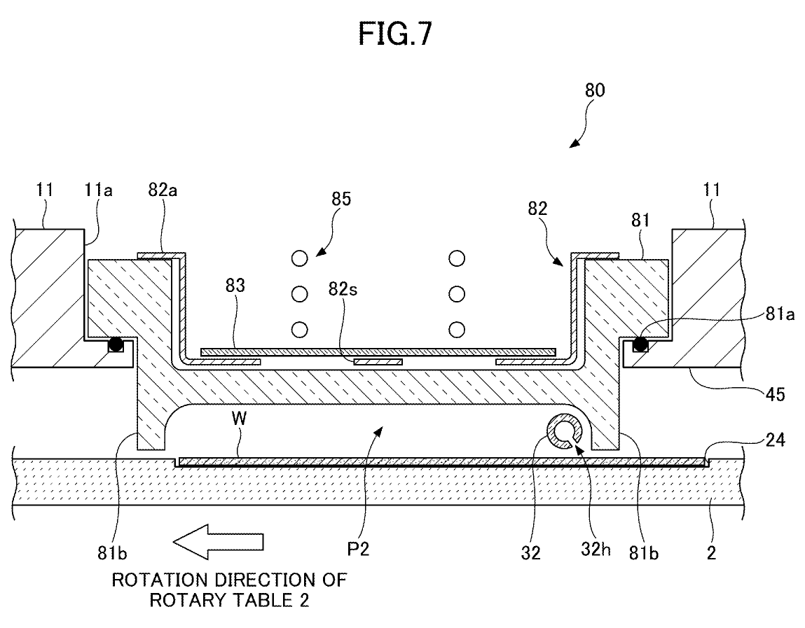

FIG. 4 illustrates a cross-section of the vacuum chamber 1 along the circumferential direction of the rotary table 2. As illustrated in FIG. 4, the protruding portion 4 is attached to the underside of the top plate 11. Therefore, inside the vacuum chamber 1, there are first top inner surfaces 44 and second top inner surfaces 45. The first top inner surfaces 44 correspond to the lower surfaces of the protruding portions 4 and are flat and low. The second top inner surfaces 45 are located on both circumferential sides of the first top inner surfaces 44 and are positioned higher than the first top inner surfaces 44. The first top inner surfaces 44 have a sectoral planar shape with their tops cut in an arc. A groove 43 extending in the radial direction is formed at a circumferential center of one protruding portion 4. The separation gas nozzle 42 is accommodated in the groove 43. A groove 43 is also formed in another protruding portion 4, and the separation gas nozzle 41 is accommodated in the groove 43. The process gas nozzle 31 is provided in a space 481 below one of the second top inner surfaces 45. The process gas nozzle 32 (FIG. 7) is provided in a space 482 below another of the second top inner surfaces 45. The process gas nozzles 31 and 32 are provided in the vicinity of the substrate W, spaced apart from the second top inner surfaces 45.

The separation gas nozzle 42 is provided with discharge holes 42h (see FIG. 4) opening toward the rotary table 2. The discharge holes 42h are arranged along a longitudinal direction of the separation gas nozzle 42 at intervals of, for example, 10 mm. Similar to the separation gas nozzle 42, the separation gas nozzle 41 is also provided with discharge holes (not shown) opening toward the rotary table 2. The discharge holes are arranged along a longitudinal direction of the separation gas nozzle 41 at intervals of, for example, 10 mm.

The first top inner surfaces 44 define, with the rotary table 2, a separation space H, which is a narrow space. When the separation gas is supplied from the discharge holes 42h of the separation gas nozzle 42, the separation gas flows toward the space 481 and the space 482 through the separation space H. In this case, the volume of the separation space H is smaller than the volumes of the spaces 481 and 482. Accordingly, the separation gas can increase the pressure in the separation space H to a higher level than the pressures in the spaces 481 and 482. That is, the separation space H being at a higher pressure is formed between the spaces 481 and 482. Further, the separation gas flowing out from the separation space H into the spaces 481 and 482 acts as a counterflow against the source gas from the adsorption region P1 and the nitriding gas from the nitriding region P2. Thus, the source gas from the adsorption region P1 and the nitriding gas from the nitriding region P2 are separated by the separation space H. Therefore, it is possible to reduce mixing and reaction between the source gas and the nitriding gas in the vacuum chamber 1.

A height h1 of the first top inner surface 44 relative to the upper surface of the rotary table 2 is set in consideration of a pressure in the vacuum chamber 1 during processing of the substrate, a rotational speed of the rotary table 2, a supply amount of the separation gas, and the like. The height h1 is set to a value suitable for increasing a pressure in the separation space H to a higher level than pressures in the spaces 481 and 482.

A lower surface of the top plate 11 is provided with a projecting portion 5 (FIGS. 2 and 3) that surrounds an outer periphery of the core 21 configured to fix the rotary table 2. The projecting portion 5 is continuous with, for example, radially inner portions of the protruding portions 4, and the lower surface of the projecting portion 5 is formed at the same height as the first top inner surfaces 44.

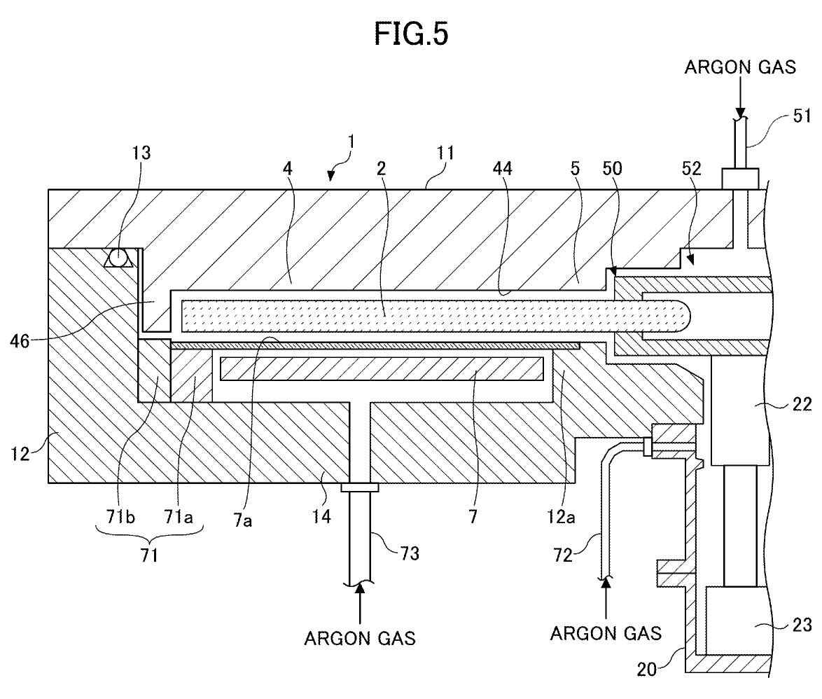

FIG. 1, which has been referred to previously, corresponds to a cross-sectional view taken along line I-I of FIG. 3, and illustrates a region where the second top inner surfaces 45 are provided. Meanwhile, FIG. 5 is a cross-sectional view illustrating a region where one first top inner surface 44 is provided. As illustrated in FIG. 5, a bent portion 46 is formed at peripheral portion (a portion toward an outer edge of the vacuum chamber 1) of the sectoral protruding portion 4 so as to bend in an L-shape and face an outer end surface of the rotary table 2. Similar to the protruding portion 4, the bent portion 46 reduces intrusion of the source gas and the nitriding gas from both sides of the separation region D, thereby reducing mixing of the source gas and the nitriding gas. The sectoral protruding portion 4 is provided on the top plate 11, and the top plate 11 can be removed from the chamber body 12. Therefore, there is a slight gap between the outer peripheral surface of the bent portion 46 and the chamber body 12. A gap between the inner peripheral surface of the bent portion 46 and the outer end surface of the rotary table 2, and the gap between the outer peripheral surface of the bent portion 46 and the chamber body 12 are each set to, for example, dimensions substantially the same as the height of the first top inner surface 44 with respect to the upper surface of the rotary table 2.

An inner peripheral wall of the chamber body 12 is formed on a vertical surface close to the outer peripheral surface of the bent portion 46 in the separation region D as illustrated in FIG. 5. As illustrated in FIG. 1, an inner wall of the chamber body 12 is recessed outward in portions other than the separation regions D. The recess extends from a portion facing the outer end surface of the rotary table 2 to the bottom 14. For convenience of explanation, a recessed portion having a substantially rectangular cross-sectional shape will hereinafter be referred to as an exhaust region E. Specifically, an exhaust region communicating with the adsorption region P1 is referred to as a first exhaust region E1, and a region communicating with the nitriding region P2 is referred to as a second exhaust region E2. As illustrated in FIGS. 1 to 3, a first exhaust port 61 and a second exhaust port 62 are formed respectively at the bottoms of the first exhaust region E1 and the second exhaust region E2. As illustrated in FIG. 1, the first exhaust port 61 is connected to a vacuum pump 64 via an exhaust tube 63. Similarly, the second exhaust port 62 is connected to another vacuum pump 64 via another exhaust tube 63. Each exhaust tube 63 is provided with a pressure controller 65.

As illustrated in FIGS. 1 and 5, a heater unit 7 is provided in a space between the rotary table 2 and the bottom 14 of the vacuum chamber 1. The heater unit 7 heats the substrate W on the rotary table 2 via the rotary table 2 to a temperature determined by a process recipe. An annular cover member 71 is provided below and in the vicinity of the periphery of the rotary table 2 (FIG. 5). The cover member 71 partitions between the atmosphere, which extends from the space above the rotary table 2 to the exhaust regions E1 and E2, and the atmosphere in which the heater unit 7 is placed, thereby minimizing the intrusion of gas into the regions below the rotary table 2. The cover member 71 includes an inner member 71a and an outer member 71b. The inner member 71a is provided so as to face the outer edge of the rotary table 2 and a region outward of the outer edge from below. The outer member 71b is provided between the inner member 71a and the inner wall surface of the vacuum chamber 1. The outer member 71b is provided below and in proximity to the bent portions 46 formed at the outer edges of the protruding portions 4 in the separation regions D. The inner member 71a surrounds the heater unit 7 over the entire circumference, below the outer edge of the rotary table 2 (and below a portion slightly outward from the outer edge).

The bottom 14 at a position closer to the rotation center than the space in which the heater unit 7 is disposed projects upward so as to approach the core 21, which is positioned near the center of the lower surface of the rotary table 2, thereby forming the projecting portion 12a. A narrow space is formed between the projecting portion 12a and the core 21, and a clearance between the rotary shaft 22 and an inner peripheral surface of a through-hole for the rotary shaft 22 penetrating the bottom 14 is also narrow. These narrow spaces communicate with the case body 20. The case body 20 is provided with a purge gas supply tube 72 configured to supply a purge gas into the narrow spaces to purge the same. The purge gas is, for example, argon gas. The bottom 14 of the vacuum chamber 1 is provided with purge gas supply tubes 73 at predetermined angular intervals in the circumferential direction below the heater unit 7 to purge the space where the heater unit 7 is disposed. FIG. 5 illustrates one purge gas supply tube 73. A lid member 7a is provided between the heater unit 7 and the rotary table 2 to circumferentially cover a space between the inner peripheral wall of the outer member 71b (the upper surface of the inner member 71a) and the upper end of the projecting portion 12a, thereby minimizing the intrusion of gas into the region where the heater unit 7 is provided. The lid member 7a is formed of, for example, quartz.

A separation gas supply tube 51 is connected to the center of the top plate 11 of the vacuum chamber 1. The separation gas supply tube 51 supplies a separation gas to a space 52 positioned between the top plate 11 and the core 21. The separation gas supplied into the space 52 is discharged toward the periphery along the surface of the rotary table 2 close to a substrate stage region via a narrow space 50 between the projecting portion 5 and the rotary table 2. The space 50 can be maintained at a pressure higher than that of a space 481 and a space 482 by the separation gas. Thus, the space 50 reduces mixing of the source gas supplied to the adsorption region P1 and the nitriding gas supplied to the nitriding region P2 through a center region C. That is, the space 50 (or the center region C) functions in the same manner as the separation space H (or the separation regions D).

As illustrated in FIGS. 2 and 3, a transfer port 15 is formed in a sidewall of the vacuum chamber 1. The transfer port 15 is configured to transfer the substrate W between an external transfer arm 10 and the rotary table 2. The transfer port 15 is opened and closed by a gate valve (not shown). The substrate W is transferred to and from the transfer arm 10 at a position facing the transfer port 15. The lift pins (not shown) for the transfer and a lift mechanism thereof (not shown) are provided at a position below the rotary table 2 corresponding to the transfer position. The lift pins penetrate the stage 24 and are configured to lift the substrate W from the underside of the substrate W.

The substrate processing apparatus includes a controller 100. The controller 100 is an electronic circuit such as a central processing unit (CPU), a field programmable gate array (FPGA), or an application specific integrated circuit (ASIC). The controller 100 executes various control operations described herein by executing instruction codes stored in a memory or by being designed as a circuit for a specific use.

### Plasma Source

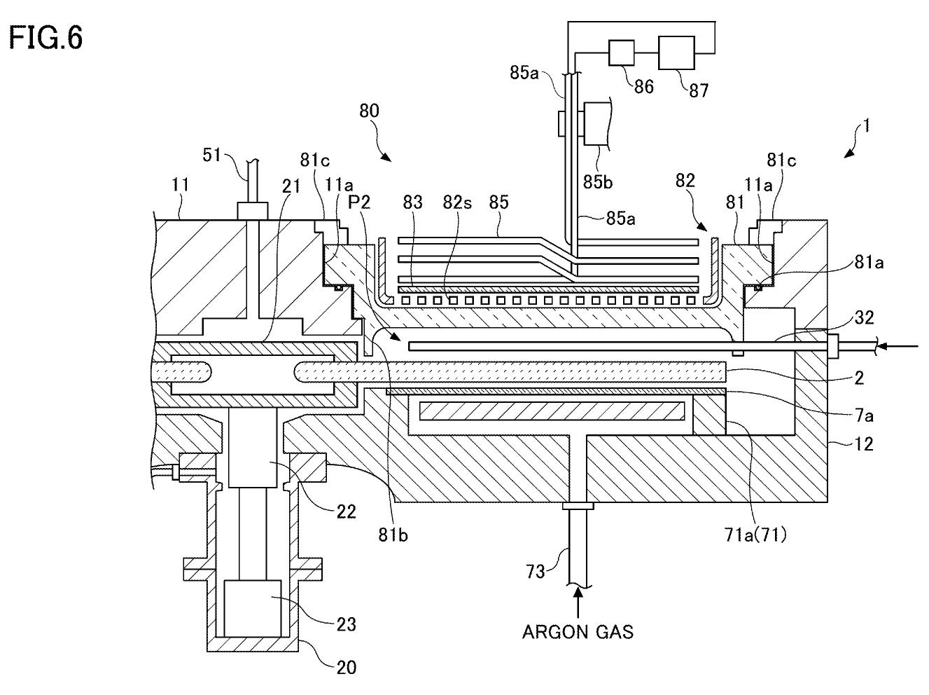

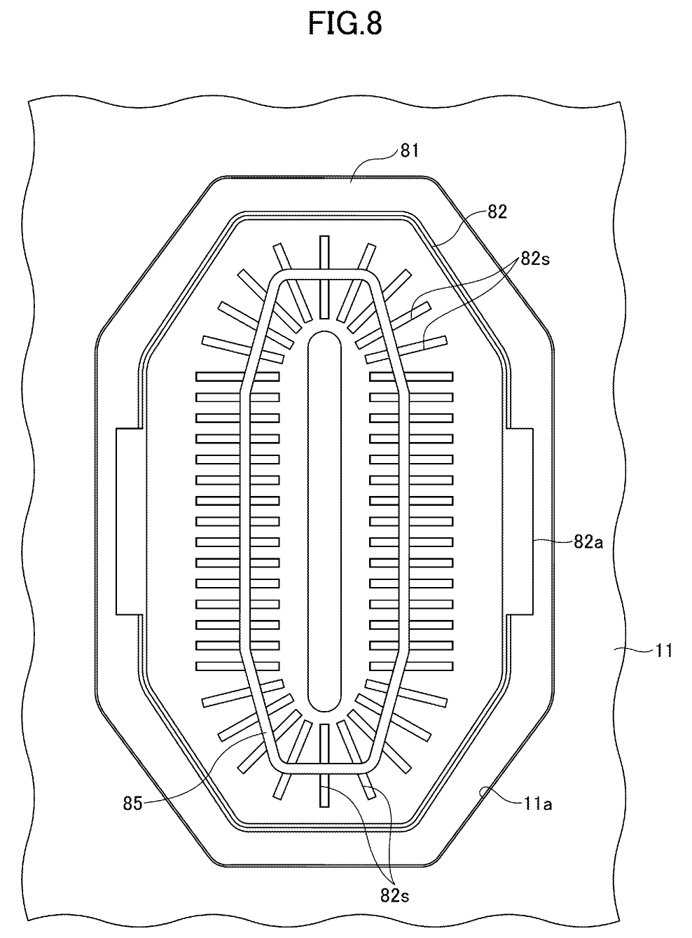

The plasma source 80 will be described with reference to FIGS. 6 to 8. FIGS. 6 and 7 are cross-sectional views illustrating an example of the plasma source 80. FIG. 6 corresponds to a cross-sectional view taken along the radial direction of the rotary table 2, and FIG. 7 corresponds to a cross-sectional view taken along a direction orthogonal to the radial direction of the rotary table 2. FIG. 8 is a plan view illustrating the example of the plasma source 80. In FIGS. 6 to 8, some members are illustrated in a simplified manner.

As illustrated in FIG. 6, the plasma source 80 includes a frame member 81, a Faraday shielding plate 82, an insulating plate 83, and an antenna 85. The frame member 81 is formed of a high-frequency transmissive material. The frame member 81 has a recess formed in an upper surface of the frame member 81 and is fitted into an opening 11a formed in the top plate 11. The Faraday shielding plate is accommodated in the recess of the frame member 81 and has a substantially box-like shape with an open top. The insulating plate 83 is disposed on a bottom surface of the Faraday shielding plate 82. The antenna 85 is supported above the insulating plate 83. The antenna 85 has a substantially octagonal planar coil shape.

The opening 11a of the top plate 11 has stepped portions. A groove is formed in one of the stepped portions along the entire periphery. A seal member 81a is fitted into the groove. The seal member 81a is, for example, an O-ring. The frame member 81 has stepped portions corresponding to the stepped portions of the opening 11a. In a state in which the frame member 81 is fitted into the opening 11a, an underside of one of the stepped portions comes into contact with the seal member 81a. This maintains airtightness between the top plate 11 and the frame member 81. A pressing member 81c is provided on an outer periphery of an upper surface of the frame member 81. The pressing member 81c presses the frame member 81 downward against the top plate 11. This further ensures that airtightness is maintained between the top plate 11 and the frame member 81.

A lower surface of the frame member 81 faces the rotary table 2 in the vacuum chamber 1. On the outer periphery of the lower surface of the frame member 81, a protrusion 81b extending downward (toward the rotary table 2) is provided along the entire periphery. A lower surface of the protrusion 81b is in proximity to the surface of the rotary table 2. A space (the nitriding region P2) is defined above the rotary table 2 by the protrusion 81b, the surface of the rotary table 2, and the lower surface of the frame member 81. The process gas nozzle 32 penetrating the protrusion 81b extends through the nitriding region P2. The process gas nozzle 32 supplies the nitriding gas from the supply source GS2 into the vacuum chamber 1 as previously mentioned.

The discharge holes 32h are formed in the process gas nozzle 32 along the longitudinal direction thereof at predetermined intervals (e.g., 10 mm). The process gas nozzle 32 discharges the nitriding gas from the discharge holes 32h. As illustrated in FIG. 7, the discharge hole 32h is inclined from the direction perpendicular to the rotary table 2 toward the upstream of the rotation direction of the rotary table 2. Therefore, the nitriding gas supplied from the process gas nozzle 32 is discharged in the direction opposite to the rotation direction of the rotary table 2, that is, toward the gap between the lower surface of the protrusion 81b and the surface of the rotary table 2. This minimizes the separation gas flowing into the nitriding region P2 from the space below the second top inner surfaces 45 positioned closer to the upstream than the plasma source 80 along the rotation direction of the rotary table 2. As described above, the protrusion 81b formed along the outer periphery of the lower surface of the frame member 81 is in proximity to the surface of the rotary table 2. Therefore, the pressure in the nitriding region P2 can be easily maintained high by the nitriding gas from the process gas nozzle 32. This also minimizes the separation gas flowing into the nitriding region P2.

The Faraday shielding plate 82 is formed of a conductive material such as a metal. The Faraday shielding plate 82 is grounded. As illustrated in FIG. 8, slits 82s are formed at a bottom of the Faraday shielding plate 82. Each slit 82s extends substantially orthogonal to a corresponding side of the antenna 85 having a substantially octagonal planar shape.

As illustrated in FIGS. 7 and 8, the Faraday shielding plate 82 has a support portion 82a which bends outward at two upper ends. The support portion 82a is supported on the upper surface of the frame member 81 so that the Faraday shielding plate 82 is supported at a predetermined position in the frame member 81.

The insulating plate 83 is formed of, for example, quartz glass. The insulating plate 83 is slightly smaller in size than a bottom surface of the Faraday shielding plate 82 and is placed on the bottom surface of the Faraday shielding plate 82. The insulating plate 83 insulates the Faraday shielding plate 82 and the antenna 85. The insulating plate 83 transmits downward high-frequency waves radiated from the antenna 85.

The antenna 85 is formed by winding, for example, three times, a hollow copper tube (pipe) so as to have a substantially octagonal planar shape. Cooling water can be circulated in the pipe, thereby preventing the antenna 85 from being heated to a high temperature caused by the high-frequency waves supplied to the antenna 85. The antenna 85 is provided with an erecting portion 85a, and a support portion 85b is attached to the erecting portion 85a. The support portion 85b maintains the antenna 85 at a predetermined position in the Faraday shielding plate 82. A high-frequency power supply 87 is connected to the support portion 85b via a matching box 86. The high-frequency power supply 87 generates high-frequency waves having a frequency of, for example, 13.56 MHz.

According to the plasma source 80 having such a configuration, when high-frequency power is supplied from the high-frequency power supply 87 to the antenna 85 via the matching box 86, an electromagnetic field is generated by the antenna 85. Since an electric field component of the electromagnetic field is shielded by the Faraday shielding plate 82, the electric field component cannot propagate downward. On the other hand, a magnetic field component propagates to the nitriding region P2 through the slits 82s of the Faraday shielding plate 82. Due to the magnetic field component, plasma is generated from the nitriding gas supplied from the process gas nozzle 32 to the nitriding region P2.

### Gas Heater

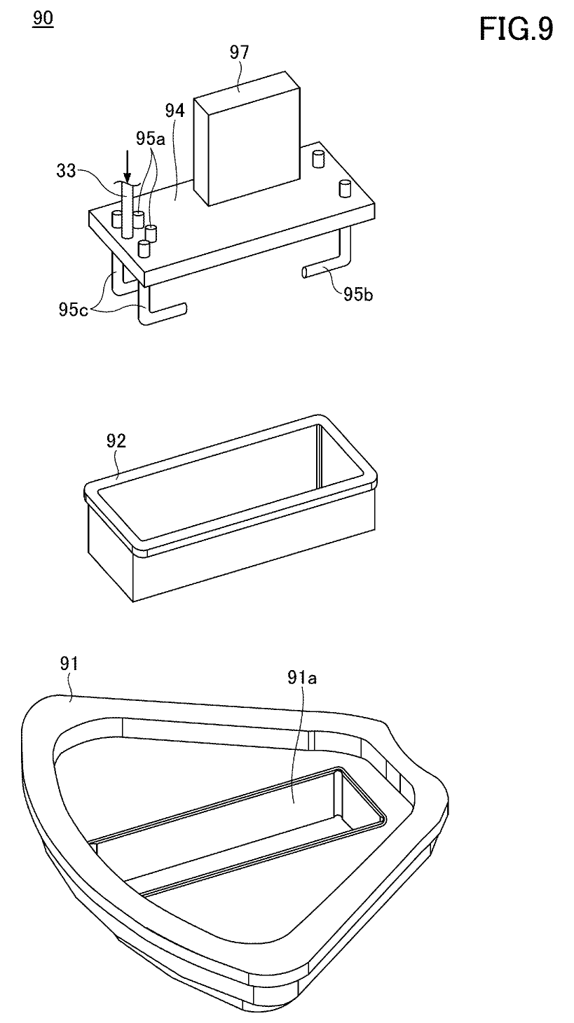

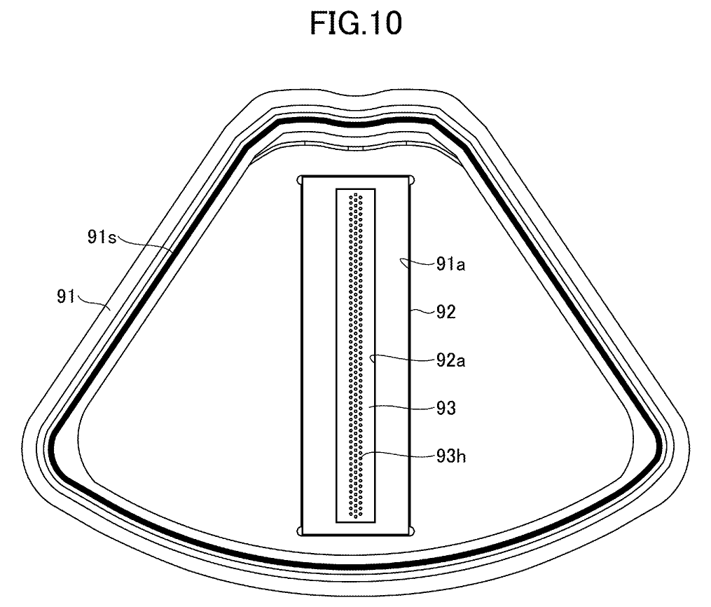

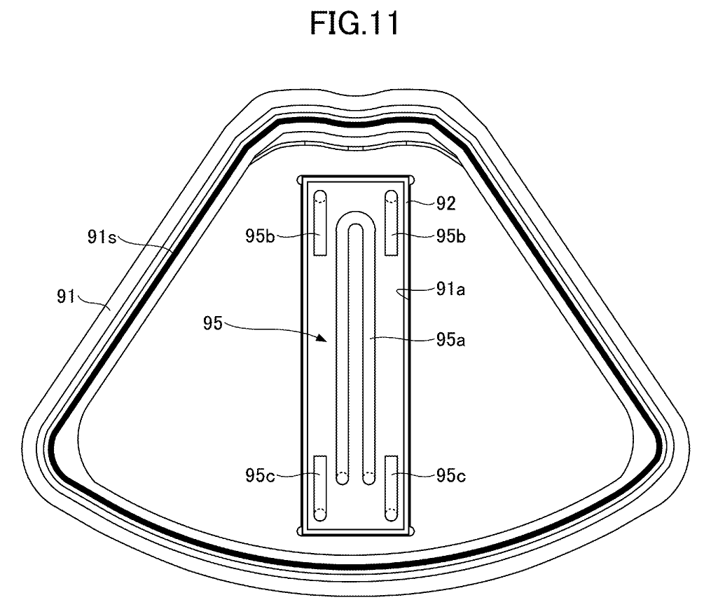

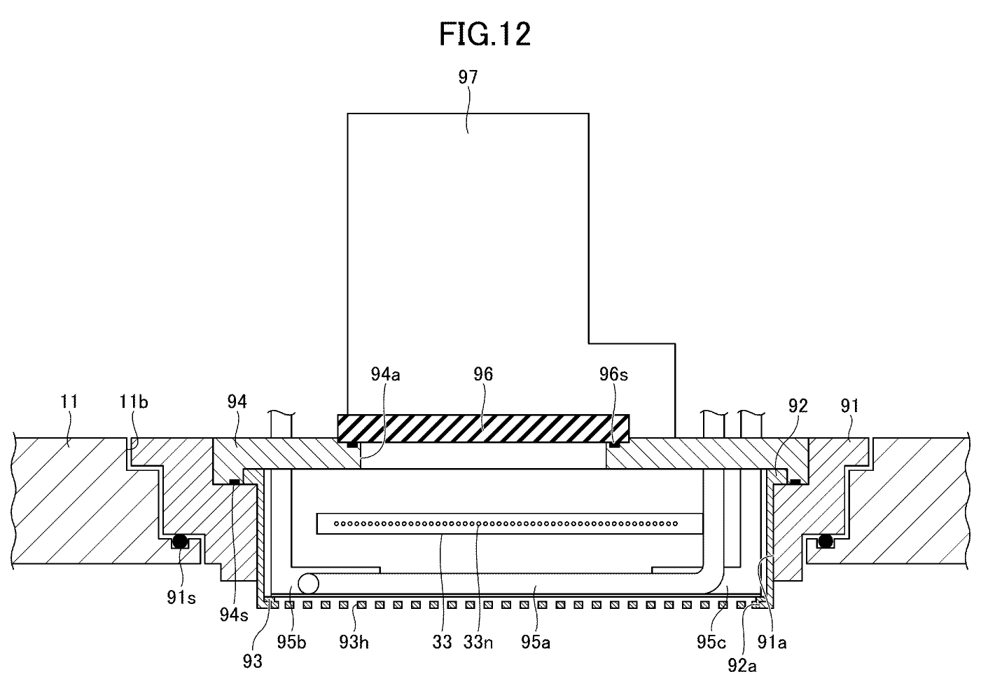

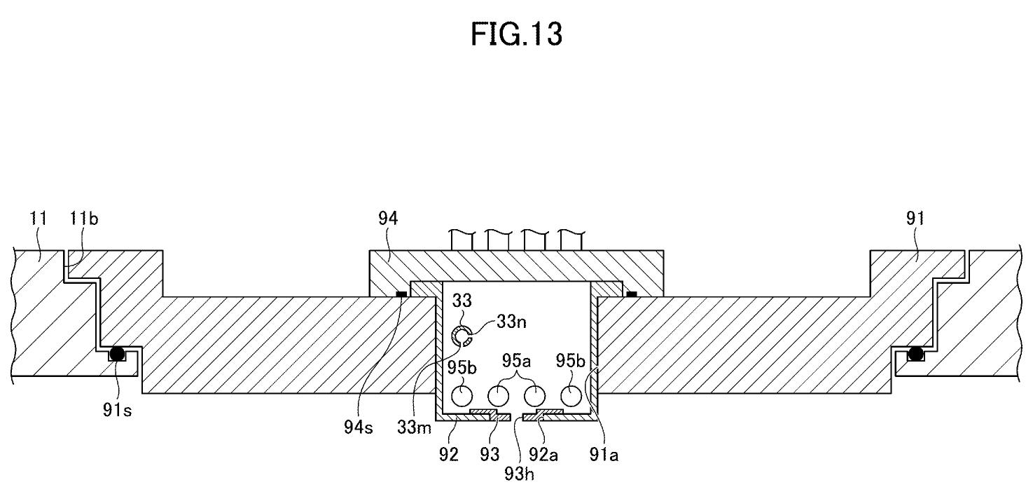

The gas heater 90 will be described with reference to FIGS. 9 to 13. FIG. 9 is an exploded perspective view illustrating an example of the gas heater 90. FIGS. 10 and 11 are plan views illustrating the example of the gas heater 90. FIGS. 10 and 11 are bottom views of a base member 91. FIG. 11 illustrates a configuration inside a quartz box 92, and part of the quartz box 92 and a distribution plate 93 are omitted. FIGS. 12 and 13 are cross-sectional views illustrating the example of the gas heater 90. FIG. 12 corresponds to a cross-sectional view taken along the radial direction of the rotary table 2, and FIG. 13 corresponds to a cross-sectional view taken along a direction orthogonal to the radial direction of the rotary table 2.

The gas heater 90 includes the base member 91, the quartz box 92, the distribution plate 93, a lid 94, a heater 95, a quartz window 96, and a light source 97.

The base member 91 is fitted into an opening 11b formed in the top plate 11. The opening 11b of the top plate 11 has stepped portions. A groove is formed in one of the stepped portions along the entire periphery. A seal member 91s is fitted into the groove. The seal member 91s is, for example, an O-ring. The base member 91 has stepped portions corresponding to the stepped portions of the opening 11b. In a state in which the base member 91 is fitted into the opening 11b, an underside of one of the stepped portions comes into contact with the seal member 91s. This maintains airtightness between the top plate 11 and the base member 91. The base member 91 has a sectoral planar shape with its top cut in an arc. The base member 91 has an opening 91a. The opening 91a has a rectangular planar shape extending along the radial direction of the rotary table 2.

The quartz box 92 is fitted into the opening 91a of the base member 91. The quartz box 92 has a substantially box-like shape with an open top The quartz box 92 is formed of, for example, quartz. The quartz box 92 has an opening 92a in the bottom surface. The opening 92a has a rectangular planar shape extending along the radial direction of the rotary table 2. The process gas nozzle 33 is provided inside the quartz box 92. Discharge holes 33m and 33n are formed in the process gas nozzle 33 along the longitudinal direction thereof at predetermined intervals (e.g., 10 mm). The discharge holes 33m and 33n discharge chlorine gas into the quartz box 92. The chlorine gas discharged into the quartz box 92 is retained inside the quartz box 92. As illustrated in FIG. 13, the discharge holes 33m are open toward the rotary table 2, and the discharge holes 33n are open toward the upstream of the rotation direction of the rotary table 2. In this case, the chlorine gas discharged from the discharge holes 33m and 33n is easily retained inside the quartz box 92.

The distribution plate 93 is fitted into the opening 92a of the quartz box 92. The distribution plate 93 has gas holes 93h at the bottom surface. The gas holes 93h may be aligned at equal intervals along the radial direction of the rotary table 2. The gas holes 93h may be aligned at equal intervals along a direction orthogonal to the radial direction of the rotary table 2. The gas holes 93h discharge, toward the rotary table 2, the chlorine gas retained inside the quartz box 92.

The lid 94 is airtightly and detachably attached to the base member 91 via the seal member 94s so as to close the open top of the quartz box 92. The quartz box 92 and the lid 94 together function as a retaining portion configured to retain the chlorine gas discharged from the process gas nozzle 33. The lid 94 has a lamp opening 94a. The lamp opening 94a has a rectangular planar shape extending along the radial direction of the rotary table 2.

The heater 95 is provided inside the quartz box 92. The heater 95 is configured to heat the chlorine gas retained inside the quartz box 92. The heater 95 includes a main heater 95a, an inner heater 95b, and an outer heater 95c. The main heater 95a extends along the radial direction of the rotary table 2 entirely from the center to the outer periphery of the rotary table 2. The inner heater 95b is provided near the center of the rotary table 2. The inner heater 95b extends along the radial direction of the rotary table 2. Two inner heaters 95b may be provided and spaced apart in a direction orthogonal to the radial direction of the rotary table 2. The outer heater 95c is provided near the outer end of the rotary table 2. The outer heater 95c is provided farther from the center of the rotary table 2 than the inner heater 95b. The outer heater 95c extends along the radial direction of the rotary table 2. Two outer heaters 95b may be provided and spaced apart in a direction orthogonal to the radial direction of the rotary table 2. The main heater 95a, the inner heater 95b, and the outer heater 95c are, for example, rod heaters.

The quartz window 96 is made of quartz and is flat and rigid. The quartz window 96 has a planar shape larger than the lamp opening 94a of the lid 94. The quartz window 96 closes the lamp opening 94a of the lid 94. The quartz window 96 is airtightly and detachably attached to the lid 94 via a seal member 96s. The seal member 96s is, for example, an O-ring. The quartz window 96 transmits downward ultraviolet rays emitted from the light source 97.

The light source 97 is provided above the quartz window 96. The light source 97 emits ultraviolet rays into the quartz box 92 via the quartz window 96 to heat the chlorine gas retained inside the quartz box 92. The light source 97 is, for example, an ultraviolet LED (UV-LED) light source or an ultraviolet lamp (UV lamp) light source.

According to the gas heater 90, the chlorine gas discharged from the process gas nozzle 33 is heated by the heater 95 while being retained inside the quartz box 92. In this case, by adjusting a set temperature of the heater 95, the chlorine gas can be supplied to the substrate on the rotary table 2 while the temperature of the chlorine gas is controlled inside the quartz box 92.

### Substrate Processing Method

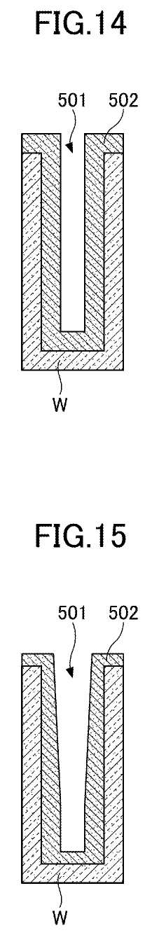

A substrate processing method according to an embodiment will be described with reference to FIGS. 14 and 15. Hereinafter, an example will be described in which a silicon film 502 formed along the surface of a recess 501 of the substrate W is etched using the aforementioned substrate processing apparatus. The following substrate processing method is performed under the control of the controller 100.

First, a gate valve (not shown) is opened, and the substrate W is transferred onto the stage 24 of the rotary table 2 from the outside via the transfer port 15 by the transfer arm 10. As illustrated in FIG. 14, the substrate W has the recess 501 in the surface thereof. The silicon film 502 is formed on the surface of the recess 501. The transfer of the substrate W is performed when the stage 24 stops at a position facing the transfer port 15. At this time, the lift pins (not shown) are raised and lowered in the direction of the bottom of the vacuum chamber 1 via the through-holes formed in the bottom surface of the stage 24. The transfer of the substrate W is performed by intermittently rotating the rotary table 2, and the substrates W are placed in respective five stages 24 of the rotary table 2.

Next, the gate valve is closed, and the vacuum pump 64 evacuates the vacuum chamber 1 to an attainable degree of vacuum. Thereafter, argon gas is discharged at a predetermined flow rate from the separation gas nozzles 41 and 42. Argon gas is also discharged at a predetermined flow rate from the separation gas supply tube 51 and the purge gas supply tubes 72 and 73. Accordingly, the pressure inside the vacuum chamber 1 is controlled to a preset processing pressure by the pressure controller 65. Then, the substrate W is heated to a first temperature by the heater unit 7 while the rotary table 2 is rotated clockwise at a predetermined rotational speed. The first temperature ranges from, for example, 350°C to 550°C, inclusive.

Next, while the substrate W is maintained at the first temperature, a mixed gas of argon gas and chlorine gas is supplied from the process gas nozzle 33. Meanwhile, the mixed gas of argon gas and chlorine gas retained inside the quartz box 92 is irradiated with ultraviolet rays emitted from the light source 97 of the gas heater 90. The mixed gas of argon gas and chlorine gas is heated by irradiation with ultraviolet rays. Accordingly, chlorine radicals are generated from the chlorine gas inside the quartz box 92. The chlorine radicals are discharged from the gas holes 93h of the distribution plate 93 toward the substrate W. In such a manner, the chlorine radicals can be supplied to the substrate W without using plasma. The mixed gas of argon gas and chlorine gas retained inside the quartz box 92 may be heated by the heater 95 of the gas heater 90. A flow rate of the chlorine gas discharged from the process gas nozzle 33 into the quartz box 92 may be adjusted so that the amount of the chlorine radicals is different in the depth direction of the recess 501.

With each rotation of the rotary table 2, the substrate W passes through the etching region P3.

When the substrate W reaches the etching region P3, the silicon film 502 is exposed to the chlorine radicals. The silicon film 502 is etched by being exposed to the chlorine radicals. Etching of the silicon film 502 by the chlorine radicals tends to be isotropic rather than anisotropic. Accordingly, as illustrated in FIG. 15, the silicon film 502 is etched with a distribution in which the amount of etching gradually increases from the bottom of the recess 501 toward the opening in the depth direction. Thus, by supplying the chlorine radicals to the substrate W, the silicon film can be etched irrespective of the substrate temperature. Therefore, it is possible to etch the silicon film 502 at a desired substrate temperature.

In the above examples, a case where the silicon film 502 to be etched is provided in advance on the surface of the recess 501 of the substrate W has been described, but the present disclosure is not limited thereto. For example, a substrate W in which the silicon film 502 is not formed may be prepared, and in the aforementioned substrate processing apparatus, the formation of the silicon film 502 to be etched and the etching of the silicon film 502 may be continuously performed. As previously mentioned, it is possible to etch the silicon film 502 at a desired substrate temperature. Thus, the substrate temperature for etching the silicon film 502 can be the same as the substrate temperature for forming the silicon film 502. Therefore, there is no need to change the temperature of the substrate W, thereby improving throughput.

According to an embodiment, the chlorine gas before being supplied to the substrate W is retained inside the quartz box 92, and the chlorine gas retained inside the quartz box 92 is irradiated with ultraviolet rays. The chlorine gas is heated by irradiation with ultraviolet rays. Accordingly, chlorine radicals are generated from the chlorine gas inside the quartz box 92 and discharged from the gas holes 93h of the distribution plate 93 toward the substrate W. The silicon film 502 formed on the substrate W is etched by being exposed to the chlorine radicals. Etching of the silicon film 502 by the chlorine radicals tends to be isotropic rather than anisotropic. Thus, the silicon film 502 is etched with a distribution in which the amount of etching gradually increases from the bottom of the recess 501 toward the opening in the depth direction. By supplying the chlorine radicals to the substrate W, the silicon film 502 can be etched irrespective of the temperature of the substrate W (the temperature of the heater unit 7) in such a manner. Therefore, it is possible to etch the silicon film 502 at a desired substrate temperature.

According to an embodiment, the silicon film 502 may be etched without using plasma. In this case, damage to members included in the substrate processing apparatus is reduced. Therefore, occurrence of particles can be reduced.

According to an embodiment, the chlorine gas may be heated by the heater 95 provided inside the quartz box 92. In this case, it is possible to adjust the etching rate of the silicon film 502.

According to an embodiment, the chlorine gas may be heated by heaters 95 (the main heater 95a, the inner heater 95b, and the outer heater 95c) provided at different positions inside the quartz box 92. In this case, the distribution of the chlorine radicals generated inside the quartz box 92 can be adjusted.

According to an embodiment, the flow rate of the chlorine gas discharged from the process gas nozzle 33 into the quartz box 92 may be adjusted so that the amount of the chlorine radicals is different in the depth direction of the recess 501. In this case, it is possible to adjust the etching shape in the depth direction of the recess 501.

According to an embodiment, the silicon film 502 may be formed along the surface of the recess 501 by using a substrate processing apparatus configured to etch the silicon film 502. In this case, the temperature of the substrate W for forming the silicon film 502 along the surface of the recess 501 may be the same as the temperature for etching the silicon film 502. In this case, it is possible to continuously perform the formation and etching of the silicon film 502 without changing the temperature of the substrate W.

### Examples

In the examples, a substrate having a silicon film on a surface thereof was prepared in advance. The silicon film was etched using the substrate processing method according to the embodiments, and the etching rate of the silicon film was measured. In the examples, an evaluation was made as to how the etching rate of the silicon film formed changes depending on the presence or absence of irradiation of the chlorine gas with ultraviolet rays from the light source 97 and the presence or absence of heating of the chlorine gas with the heater 95. The conditions in the examples are as follows.

### Common Conditions

Set temperature of the heater unit 7: 350°C

Pressure in the vacuum chamber 1: 2.0 Torr (267 Pa)

Rotational speed of the rotary table 2: 20 rpm

Types and flow rates of gases supplied from the process gas nozzle 33

Argon gas: 4,000 sccm

Chlorine gas: 50 sccm

### Condition K

Set temperature of the heater 95: 800°C

Light source 97: Off

### Condition L

Heater 95: Off

Light source 97: On

### Condition M

Set temperature of the heater 95: 800°C

Light source 97: On

### Condition X

Heater 95: Off

Light source 97: Off

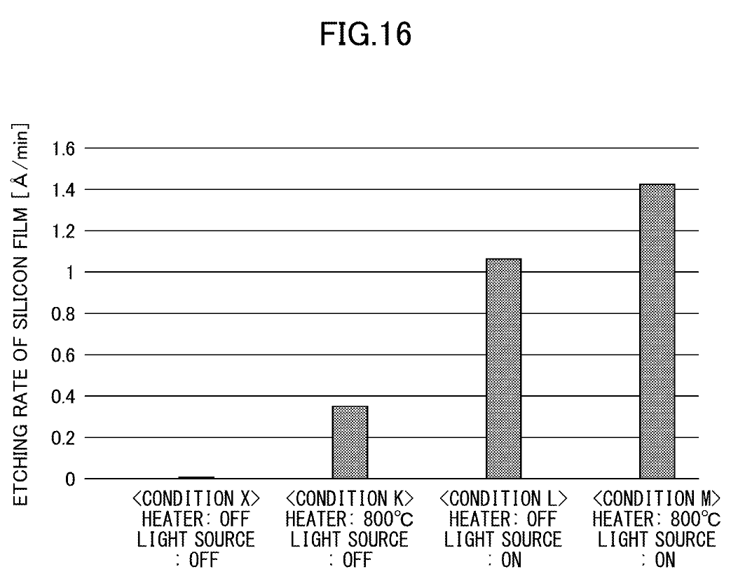

FIG. 16 is a diagram showing measurement results of etching rates of a silicon film. In FIG. 16, from the left, the etching rates [Å/min] of the silicon film under Conditions X, K, L, and M are shown in this order.

As shown in FIG. 16, the etching rate of the silicon film was 0.01 Å/min under Condition X, 0.35 Å/min under Condition K, 1.06 Å/min under Condition L, and 1.42 Å/min under Condition M.

The etching rate of the silicon film is higher under Condition K than under Condition X. From these results, it can be concluded that the etching rate of the silicon film can be increased by heating the chlorine gas retained inside the quartz box 92 with the heater 95. This is considered to result from the chlorine gas retained inside the quartz box 92 being heated by the heater 95, thereby activating chlorine molecules contained in the chlorine gas and generating active species such as chlorine radicals.

The etching rate of the silicon film is higher under Condition L than under Condition X. From these results, it can be concluded that the etching rate of the silicon film can be increased by irradiating the chlorine gas retained inside the quartz box 92 from the light source 97. This is considered to result from the chlorine gas retained inside the quartz box 92 being irradiated with ultraviolet rays, thereby activating chlorine molecules contained in the chlorine gas and generating active species such as chlorine radicals.

The etching rate of the silicon film is higher under Condition M than under Condition K and Condition L. From these results, it can be concluded that the etching rate of the silicon film can be particularly increased by heating the chlorine gas retained inside the quartz box 92 with the heater 95 while irradiating the chlorine gas with ultraviolet rays from the light source 97.

The embodiments disclosed herein are exemplary in all respects and should not be regarded as limiting. The above embodiments may be omitted, substituted or modified in various ways without departing from the scope and intent of the appended claims.

In the above embodiments, the case has been described in which the substrate processing apparatus is a semi-batch apparatus that processes substrates by rotating a rotary table on which substrates are placed within a vacuum chamber so that the substrates sequentially pass through process regions. However, the present disclosure is not limited thereto. For example, the substrate processing apparatus may be a single-wafer processing apparatus configured to process substrates one by one.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting.

1. A substrate processing method, comprising:
preparing a substrate having a silicon film on a surface thereof; and
supplying chlorine gas to the substrate, thereby etching the silicon film, wherein
the etching of the silicon film includes:
retaining, in a retaining portion, the chlorine gas before being supplied to the substrate, and
generating chlorine radicals from the chlorine gas by irradiating, with an ultraviolet ray, the chlorine gas inside the retaining portion.

2. The substrate processing method according to claim 1, wherein
the etching of the silicon film is performed without using plasma.

3. The substrate processing method according to claim 1, wherein
the etching of the silicon film includes heating the chlorine gas by a heater provided in the retaining portion.

4. The substrate processing method according to claim 3, wherein
the etching of the silicon film includes heating the chlorine gas by heaters provided at different positions in the retaining portion.

5. The substrate processing method according to claim 1, wherein
the silicon film is formed along a surface of a recess, and
the etching of the silicon film includes adjusting a flow rate of the chlorine gas so that an amount of the chlorine radical is different in a depth direction of the recess.

6. The substrate processing method according to claim 1, wherein
the preparation of the substrate includes forming the silicon film on the surface of the substrate, and
a temperature of the substrate for etching the silicon film is equal to a temperature of the substrate for forming the silicon film.

7. A substrate processing apparatus, comprising:
a vacuum chamber configured to accommodate a substrate;
a chlorine gas supply configured to supply chlorine gas to the substrate in the vacuum chamber; and
a controller, wherein
the chlorine gas supply includes:
a retaining portion configured to retain the chlorine gas before being supplied to the substrate in the vacuum chamber, and
a light source configured to emit an ultraviolet ray to irradiate the chlorine gas inside the retaining portion,
the controller is configured to execute:
preparation of the substrate having a silicon film on a surface thereof, and
supply of the chlorine gas to the substrate, thereby etching the silicon film, and
the etching of the silicon film includes:
retaining, in the retaining portion, the chlorine gas before being supplied to the substrate, and
generating chlorine radicals from the chlorine gas by irradiating, with the ultraviolet ray, the chlorine gas inside the retaining portion.

8. The substrate processing method according to claim 2, wherein
the preparation of the substrate includes forming the silicon film on the surface of the substrate, and
a temperature of the substrate for etching the silicon film is equal to a temperature of the substrate for forming the silicon film.

9. The substrate processing method according to claim 3, wherein
the preparation of the substrate includes forming the silicon film on the surface of the substrate, and
a temperature of the substrate for etching the silicon film is equal to a temperature of the substrate for forming the silicon film.

10. The substrate processing method according to claim 4, wherein
the preparation of the substrate includes forming the silicon film on the surface of the substrate, and
a temperature of the substrate for etching the silicon film is equal to a temperature of the substrate for forming the silicon film.

11. The substrate processing method according to claim 5, wherein
the preparation of the substrate includes forming the silicon film on the surface of the substrate, and
a temperature of the substrate for etching the silicon film is equal to a temperature of the substrate for forming the silicon film.
